(19) United States
(12) Patent Application Publication
(10) Pub. No.: US 2005/0184725 A1
(43) Pub. Date: Aug. 25, 2005

(54) Magnetically operable displacement pickup

(76) Inventor: Yunqiang Wang, Halver (DE)

Correspondence Address: Martin A. Farber, Esq., Suite 473, 866 United Nations Plaza, New York, NY, 10017, US

(21) Appl. No.: 10/842,832

(22) Filed: May 11, 2004

(30) Foreign Application Priority Data
May 16, 2003 (DE) 203 07 652.4

(51) Int. Cl. G01B 7/14; G01B 7/30; G01R 33/06

(52) U.S. Cl. 324/207.2; 324/207.24

(57) ABSTRACT

A a magnetically operable displacement pickup has a magnetic field sensor (2) and a magnet (1) which can be displaced along a line of movement (6). To increase the measuring length, a magnetically soft bar (4) disposed parallel to and at a distance from the line of movement (6) is provided, the magnetic field sensor (2) being disposed in front of the end face (4′) of the bar with its sensor direction pointing towards the end face (4′). A magnetic field sensor is preferably disposed in front of each end face (4′, 4″).

The invention relates to a magnetically operable displacement pickup with a magnetic field sensor and a magnet which can be displaced along a line of movement.

Such a magnetically operable displacement pickup is known from DE 38 03 293 A1. This laid-open patent application is concerned at the beginning with the problems involved in converting linear displacements into an analog current signal and presents a large number of solutions provided by the state of the art at the time. This DE 38 03 293 A1 proposes disposing two Hall sensors that are spaced apart from each other. The connecting line through the two Hall sensors runs parallel to the line of movement of the magnet, the movement of which is to be picked up. One problem with the disposition proposed by DE 38 03 293 A1 is the relatively small length of the distance which can be measured in that case. Another problem is that the great influences of the distance between the two lines on the analog output value are disadvantageous.

The invention is based on the object of taking measures to increase the measuring length.

The object is achieved by the invention specified in the claims.

Claim 1 provides in the first instance and substantially that a magnetically soft bar is disposed parallel to the line of movement. According to an advantageous configuration of the invention, the two magnetic field sensors known in principle from DE 38 03 293 A1 are used. Consequently, the magnetically soft bar extends along the connecting line through these two magnetic field sensors. In principle, however, one magnetic field sensor for the head of the bar is sufficient. The magnetic field sensor or sensors are aligned in such a way that their sensor planes are directed transversely in relation to the direction in which the bar extends. This has the consequence that the sensor direction of the two sensors is directed at the respective end face of the bar. It has been found to be particularly advantageous if the bar consists of a soft iron or of ferrite. According to a further advantageous development of the invention, the two magnetic field sensors may engage directly against the end faces of the magnetically soft bar. They are preferably Hall sensors. As a result of the configuration according to the invention, the measurable distance lengths can be increased significantly in comparison with the prior art. This is a consequence of the influence of the field lines through the magnetically soft bar. The distance dependence of the analog output signal is also considerably reduced. The soft-iron bar absorbs as it were the entire magnetic field. The field lines are concentrated within the magnetically soft bar.

Exemplary embodiments of the invention are explained below with reference to accompanying drawings, in which:

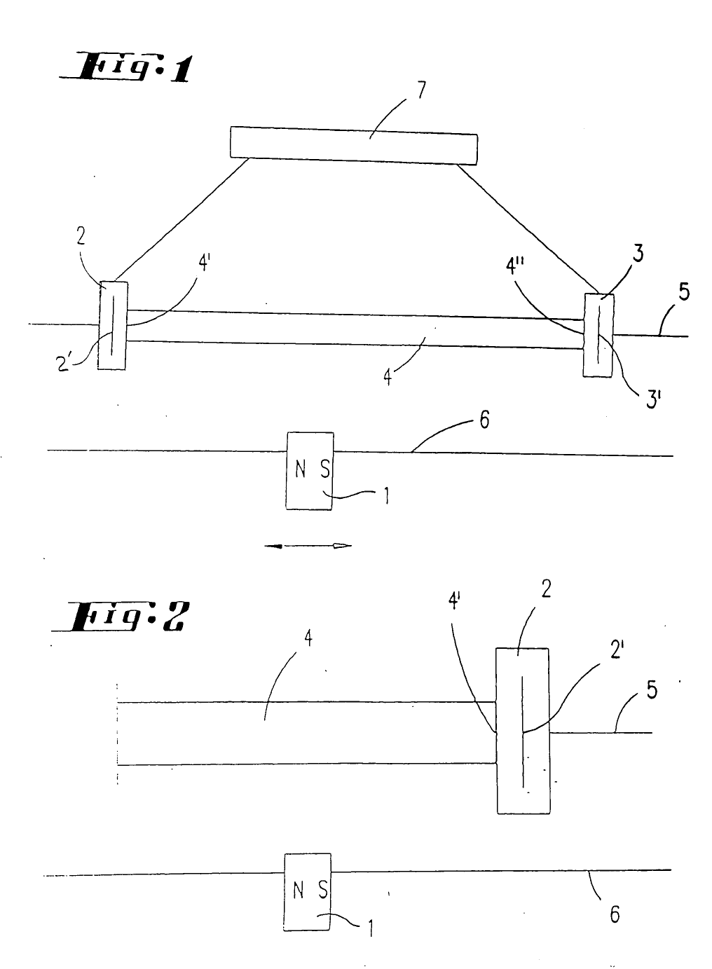

FIG. 1 shows a first exemplary embodiment of the invention in a schematic representation,

FIG. 2 shows a second exemplary embodiment of the invention in a schematic representation,

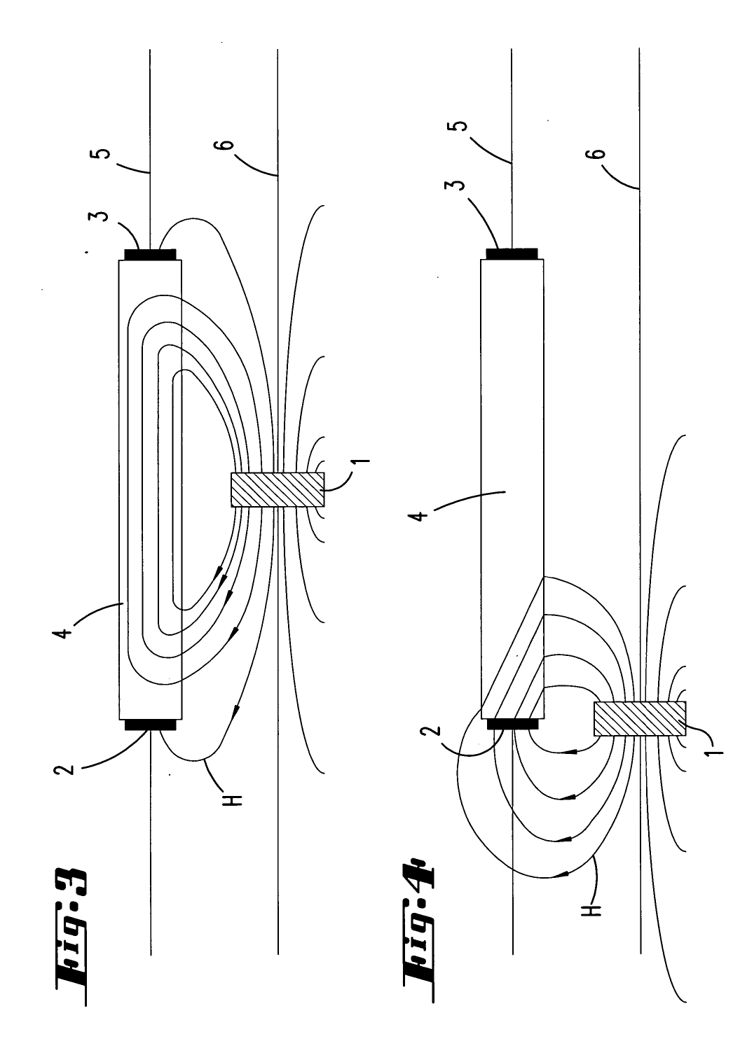

FIG. 3 shows the mode of operation of the invention with reference to an exemplary embodiment represented in FIG. 1, with the magnet positioned approximately midway between the two sensors, and

FIG. 4 shows a representation according to FIG. 3, the magnet being located level with one of the two sensors.

The apparatus represented in FIG. 1 comprises a signal processing device, which has a configuration such as that described in DE 38 03 293 A1. This signal processing device 7 is connected to two Hall sensors 2, 3 that are spaced apart from each other. Each of the two Hall sensors 2, 3 has a sensor plane 2′, 3′. The two sensor planes 2′, 3′ run parallel to each other and orthogonally in relation to a connecting line 5, which runs through the two sensors 2, 3.

Between the two Hall sensors 2, 3 there extends a magnetically soft bar 4 made of ferrite. The two mutually perpendicular end faces 4′, 4″ of the magnetically soft bar 4 run parallel to each other. The two sensors 2, 3 engage directly against the two end faces 4′, 4″. The direction in which the magnetically soft bar 4 extends consequently corresponds to the connecting line 5. The sensor direction of the two Hall sensors 2, 3 runs in the direction of the connecting line 5, that is to say is respectively directed at the end face 4′, 4″ of the bar 4.

The line of movement 6 on which the magnet 1 can move runs parallel to the connecting line 5. The line of movement 6 is at a distance from the connecting line 5. The polarity of the permanent magnet 1 is chosen such that the pole axis of the magnet 1 extends in the direction of the line of movement 6.

The output signal of the two sensors 2, 3 is connected up with the signal processing device 7 in the way described by DE 38 03 293 A1. The output signal of the signal processing device 7 substantially corresponds to that represented in DE 38 03 293 A1, but the output voltage is considerably more linear (proportional to the displacement) than it is in the latter. The output voltage proportional to the displacement covered by the magnet 1 along the line of movement 6 is also dependent to a considerably smaller extent on the distance of the line of movement 6 from the connecting line 5 or on the direction in which the magnetically soft bar 4 extends, so that small deviations from parallelism are possible.

In the case of the exemplary embodiment represented in FIG. 2, only a single magnetic field sensor 2 is located in front of the end face 4′ of the bar 4. The end face opposite from the end face 4′ is free.

If, as represented in FIG. 3, the magnet 1 is located approximately midway between the two Hall sensors 2, 3, the two sensor faces of the Hall sensors 2, 3 are passed through to an approximately equal extent by field lines H. What is important here is that, because of the magnetically soft bar, the magnetic field of the magnet 1 is substantially restricted to the half-plane on this side, which is defined by the connecting line 5.

This also applies to the functional position represented in FIG. 4. In this functional position, most of the field lines H which are generated by the permanent magnet 1 pass through the sensor face of the Hall sensor 2. The sensor face 3 opposite from the Hall sensor 2 is scarcely passed through by field lines H at all.

As a result of the measure according to the invention, the great difference in the amplitudes denoted in DE 38 03 293 A1 by the numbers I, II, III does not occur. In addition, the apparatus is considerably less susceptible to interference because of the concentration of the magnetic field lines inside the magnetically soft bar 4. This has the consequence that the measurable distance length can be increased considerably without further sensors being required in the way proposed by DE 38 03 293 A1.

All disclosed features are (in themselves) pertinent to the invention. The disclosure content of the associated/attached priority documents (copy of the prior patent application) is also hereby incorporated in full in the disclosure of the application, including for the purpose of incorporating features of these documents in claims of the present application.

1. A magnetically operable displacement pickup with a magnetic field sensor (2) and a magnet (1) which can be displaced along a line of movement (6), characterized by a magnetically soft bar (4) disposed parallel to and at a distance from the line of movement (6), the magnetic field sensor (2) being disposed in front of the end face (4′) of said bar with its sensor direction pointing towards the end face (4′).

2. The magnetically operable displacement pickup of claim 1 or in particular according thereto, characterized by two magnetic field sensors (2, 3) respectively arranged in front of one of the two end faces (4′, 4″) of the magnetically soft bar (4).

3. The magnetically operable displacement pickup of one or more of the preceding claims or in particular according thereto, characterized in that the sensor planes (2′, 3′) of the magnetic field sensors (2, 3) are aligned transversely in relation to the connecting line (5) through the two magnetic field sensors (2, 3).

4. The magnetically operable displacement pickup of one or more of the preceding claims or in particular according thereto, characterized in that the magnetically soft bar (4) is a ferrite bar.

5. The magnetically operable displacement pickup of one or more of the preceding claims or in particular according thereto, characterized in that the two magnetic field sensors (2, 3) engage against the end faces (4, 4′) of the magnetically soft bar (4).

6. The magnetically operable displacement pickup of one or more of the preceding claims or in particular according thereto, characterized in that the magnetic field sensors (2, 3) are Hall sensors.
